(19) United States
(12) Patent Application Publication
(10) Pub. No.: US 2017/0037509 A1
(43) Pub. Date: Feb. 9, 2017

(54) METHOD FOR COATING OR FILLING A POROUS MATERIAL

(71) Applicant: Tokyo Electron Limited, Tokyo (JP)

(72) Inventors: Jacques Faguet, Austin, TX (US); Junjun Liu, Austin, TX (US)

(21) Appl. No.: 15/208,441

(22) Filed: Jul. 12, 2016

Related U.S. Application Data
(60) Provisional application No. 62/192,043, filed on Jul. 13, 2015.
(60) Provisional application No. 62/287,826, filed on Jan. 27, 2016.

(51) Int. Cl. C23C 16/04; C23C 16/50; C23C 16/48

(52) U.S. Cl. CPC C23C 16/045; C23C 16/48; C23C 16/50

(57) ABSTRACT

A method is provided for coating or filling a porous material. According to one embodiment, the method includes providing the porous material, delivering precursor molecules by gas phase exposure into pores of the porous material, and reacting the precursor molecules to form a polymer inside the pores.

### CROSS-REFERENCE TO RELATED APPLICATIONS

This application is related to and claims priority to U.S. Provisional Patent Application Ser. No. 62/192,043 filed on Jul. 13, 2015, the entire contents of which are herein incorporated by reference. This application is related to and claims priority to U.S. Provisional Patent Application Ser. No. 62/287,826 filed on Jan. 27, 2016, the entire contents of which are herein incorporated by reference.

### FIELD OF INVENTION

The invention relates to a method for coating or filling a porous material.

### BACKGROUND OF THE INVENTION

Natural or man-made porous media are extensively used in material property manipulation, catalysis, photonics, gas separation and storage, cell selection, drug delivery, etc. Functionalization of the pore surface and/or filling the pores with other chemicals is critical for many applications, such as low k interlevel dielectrics, Metal Organic Framework (MOF), Covalent Organic Framework (COF), metal foams, nanocomposites, membranes, etc.

Conceptually, such a functionalization and/or filling can be done by soaking the porous medium in a proper solution or gas ambient followed by an optional drive-in anneal. However, the effectiveness of such a rudimentary approach may not be guaranteed depending on the chemistry, pore morphology, size of the functionalizing agent, and the required degree of pore surface coverage.

One critical challenge to sufficient coating or filling of a porous medium is the difficult choice of filling material. To coat all the pore surfaces would require delivery of the filling agent everywhere in the bulk of the porous medium. The coating has to be thermally stable, and very often needs to retain some functionality. It may not be that difficult with the conventional spin-coating or vapor deposition when the pore size is relatively big, such as in the case of macroporous materials which have pore diameter greater than 50 nm, however, it can be difficult when the pore size becomes very small as in the case of microporous materials which have pore diameter smaller than 2 nm and mesoporous materials which have pore diameter between 2 nm and 50 nm.

The fundamental reason for this difficulty lies in the conflicting property requirements for the filling agent, which results in a very narrow range of useful processing conditions. For example, smaller molecules usually diffuse better, have better surface mobility in vapor diffusion, have lower viscosity in solution delivery, but they are not as thermally stable as larger molecules. The thermal and chemical stability typically require a certain degree of crosslinking of the filling agent, but a fully crosslinked agent may not be as functional as often needed for surface functionality.

### SUMMARY OF THE INVENTION

A method is provided for coating or filling a porous material. According to one embodiment, the method includes providing the porous material, delivering precursor molecules by gas phase exposure into pores of the porous material, and reacting the precursor molecules to form a polymer or oligomer inside the pores.

According to another embodiment, the method includes providing a porous material, delivering precursor molecules by gas phase exposure into pores of the porous material, where the precursor molecules include monomers or dimers of low molecular weight organic compounds that are capable of polymerization, and reacting the precursor molecules to form a polymer inside the pores, wherein the reacting is performed by exposing the porous material to initiator molecules that thermally decompose to form free radicals.

### BRIEF DESCRIPTION OF THE DRAWINGS

In the accompanying drawings:

FIG. 1 is a process flow diagram for coating or filling a porous material according to an embodiment of the invention;

FIGS. 2A-2E schematically illustrate through cross-sectional views a method for coating or filling a porous material with a polymer;

FIGS. 3A-3D show a chain-growth polymerization process according to one embodiment of the invention;

FIG. 4 schematically shows free radical polymerization according to an embodiment of the invention; and

FIGS. 5A-5C show a step-growth polymerization process according to one embodiment of the invention.

### DETAILED DESCRIPTION OF SEVERAL EMBODIMENTS

Methods for processing a porous material on a substrate, such as a microelectronic workpiece, are described in various embodiments. One skilled in the relevant art will recognize that the various embodiments may be practiced without one or more of the specific details, or with other replacement and/or additional methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

Reference throughout this specification to “one embodiment” or “an embodiment” means that a particular feature, structure, material, or characteristic described in connection with the embodiment is included in at least one embodiment of the invention, but do not denote that they are present in every embodiment. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments. Various additional layers and/or structures may be included and/or described features may be omitted in other embodiments.

“Porous material” as used herein can refer to many different types of materials. One example includes a porous thin film on a hard substrate. Another example includes an organic membrane, for example a self-standing sieve that may be used for osmosis, filtration, and fluid treatment. However, other types of porous materials are contemplated and may be used. Porous materials are often classified as macroporous materials containing pores with diameters greater than 50 nm, mesoporous materials containing pores with diameters between 2 nm and 50 nm, and microporous materials containing pores with diameters less than 2 nm. Examples of mesoporous materials include certain types of silica and alumina, and examples of microporous materials include zeolites and metal-organic frameworks (MOF).

“Porous Material” can also refer to inhomogeneous materials containing a nanostructured surface layer or embedded nanostructured layer(s). Examples are substrates with nanometer scale patterns on the top surface, and laminated stack of porous materials and solid materials. Embodiments of the invention can be applied to any material system with accessible free volume.

“Substrate” as used herein generically refers to the object being processed in accordance with the invention. The substrate may include any material portion or structure of a device, particularly a semiconductor or other electronics device, and may, for example, be a base substrate structure, such as a semiconductor substrate or a layer on or overlying a base substrate structure such as a thin film. Thus, substrate is not intended to be limited to any particular base structure, underlying layer or overlying layer, patterned or unpatterned, but rather, is contemplated to include any such layer or base structure, and any combination of layers and/or base structures. The description below may reference particular types of substrates, but this is for illustrative purposes only and not limitation.

According to one embodiment of the invention, a method is provided for functionalization or coating of an inside surface of a porous material, while leaving sufficient connected free volume in the porous material for further processing.

According to another embodiment of the invention, a method is provided for forming a sacrificial template, where complete or near complete fill of the pores of a porous material with a stabilized sacrificial material (e.g., polymer) is targeted, combined with subsequent complete removal of the sacrificial material and recovery of the original pores of the porous material.

According to one embodiment of the invention, a process sequence is described where precursor molecules (e.g., monomers) are exposed in gas phase to a porous material. The gas phase exposure results in adsorption of the precursor molecules on inside surfaces/walls of connected pores of the porous material. The adsorption can be controlled through gas phase composition, gas pressure, substrate temperature, and Pm/Psat ratio, where Pm refers to the partial pressure of the precursor molecules (monomers) and Psat refers to the saturation pressure of the precursor molecules at substrate surface temperature. Depending on the size of the precursor molecules and the interaction with the pore walls, the precursor molecules can diffuse into the porous material either through interconnected pores, or through the molecular spacing in the loose molecular structure of a porous material. The adsorbed precursor molecules form a polymer in the pores through a polymerization process. The polymer has high molecular weight that provides thermal stability up to a temperature at which the lower molecular weight molecules may start to either desorb or decompose into lighter molecules that then desorb.

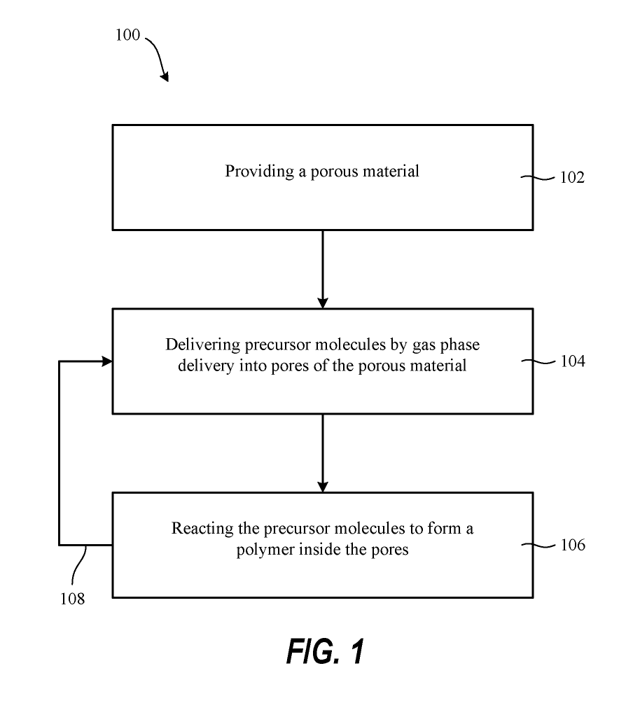

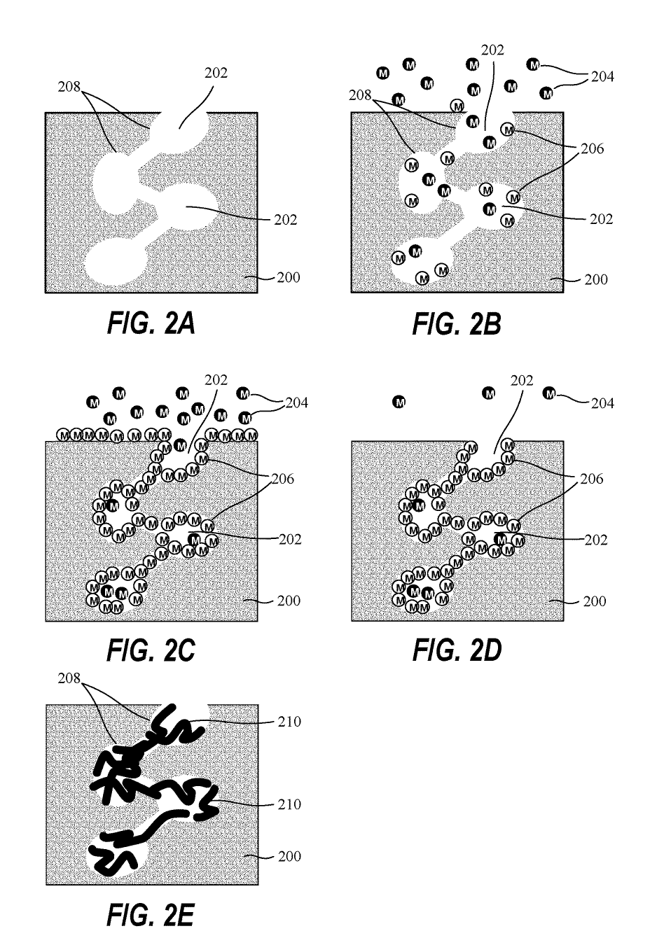

Reference will now be made to FIGS. 1 and 2 to illustrate some embodiments of the invention. FIG. 1 is a process flow diagram for coating or filling a porous material according to an embodiment of the invention, and FIGS. 2A through 2E schematically illustrate through cross-sectional views a method for coating or filling a porous material with a polymer according to an embodiment of the invention. The process flow 100 in FIG. 1A includes, in 102, providing a porous material 200 containing interconnected pores 202. The porous material 200 includes pores 202 that may be formed by the removal of a pore-forming agent during the deposition of the porous material 200 and/or during a subsequent curing process. The pores 202 can be characterized by an average pore diameter. The porous material 200 contains pore walls 208 around the pores 202.

The porous material 200 may be treated to activate the pore walls 208 for polymerization. The treating can include one or more steps selected from the group consisting of pre-coating the pores with a chemical, exposing the porous material to a reactive gas containing an oxidation species (e.g., H₂O) or a reducing species (e.g., H₂), exposing the porous material to UV light, exposing the porous material to an electron beam or ion beam, and exposing the porous material to a gas phase plasma. Examples of the chemical include bi-functional or multifunctional molecules, for example silylation agents such as Hexamethyldisilazane (HMDS) and Trimethylchlorosilane (TMCS).

Referring to FIGS. 1 and 2B, the process flow 100 further includes, in 104, delivering precursor molecules 204 by gas phase exposure into the pores 202 of the porous material 200. Once inside the pores 202, the precursor molecules 204 adsorb on the pore walls 208 and form adsorbed precursor molecules 206.

According to some embodiments of the invention, the precursor molecules 204 can include monomers or dimers of low molecular weight (<900 daltons) organic compounds. Examples include organic compounds that are capable of chain propagation of polymer chains when polymerization is triggered. In one example, the precursor molecules 204 can include a vinyl functional group (—C═C—). The name vinyl is used for any compound that contains that carbon-carbon double bond, namely R—C═C—R′, where R and R′ are any group of atoms. Examples include alkenes which are unsaturated hydrocarbons containing at least one carbon-carbon double bond. The simplest acyclic alkene with only one double bond and no other functional groups, form a homologous series of hydrocarbons with the general formula CₙH₂ₙ. The simplest alkene is ethylene (C₂H₄) which is a colorless gas at room temperature.

The polymerization can also be step-by-step growth. One example is condensation polymerization where molecules join together—losing small molecules as by-products, for example water or methanol. In dehydration synthesis, monomers with hydroxyl groups (—OH) on either end react with monomers with freely ionized (—H) on either end to form a polymer by losing water. For example, nylon is a condensation polymer formed by reacting a di-amine (R—(NH₂)₂) with a di-carboxyl acid (R′—(COOH)₂). Polyester is a condensation polymer formed by reacting a diol (R—(OH)₂) with a di-acid (R′—(COOH)₂).

FIG. 2C schematically shows further gas exposure of the precursor molecules 204 into the pores 202 and an increase in the number of adsorbed precursor molecules 206 on the pore walls 208. The extent of adsorption of the precursor molecules 204 on the pore walls 208 can be controlled through gas phase composition, pressure, substrate temperature, and Pm/Psat ratio.

Once complete or near complete coverage of the adsorbed precursor molecules 206 is achieved on the pore walls 208, the gas phase exposure may be stopped. Under these conditions, the adsorbed precursor molecules 206 may desorb if they are not located inside the pores 202. This is schematically shown in FIG. 2D.

During or following the gas phase exposure of the precursor molecules 204, the porous material 200 may be heat-treated to provide kinetic control over the pore filling profile which can include further driving the precursor molecules 204 into the porous material 200. In one example, this may be achieved by generating a vertical temperature gradient across a thickness of the porous material 200, extending from the top surface of the porous material 200 to a bottom surface of the porous material 200. The temperature can be either increase or decrease from the top surface of the porous material 200 to the bottom surface of the porous material 200. The temperature can be increased/decreased by applying more/less heat to porous material 200 from the top than from the bottom. Further, any unwanted or excess precursor molecules 204 on the top horizontal surface of the porous material 200 may be removed by heat-treating during or following the gas phase exposure.

In addition, or alternatively, to further drive the precursor molecules 204 into the porous material 200, and to remove any unwanted or excess precursor molecules 204 from the top surface of the porous material 200 may be achieved by exposing the porous material 200 to electromagnetic (EM) radiation, where the EM radiation can include emission at a wavelength within the ultraviolet (UV) spectrum, visible spectrum, infrared (IR) spectrum, or microwave spectrum, or combination thereof.

Referring to FIGS. 1 and 2E, the process flow 100 further includes, in 106, reacting the adsorbed precursor molecules 206 through a polymerization process to form a polymer 210 inside the pores 202. According to one embodiment, steps 104 and 106 may be performed simultaneously, sequentially, or over-lapping one another.

A polymerization process is a process of reacting monomer or dimer molecules together in a chemical reaction to form polymer chains or three-dimensional networks. The polymerization process may be characterized by the step-growth reaction between functional groups of monomers or dimers, or chain-growth polymerization involving linking together molecules by incorporating double or triple carbon-carbon bonds.

As depicted in FIG. 2E, the polymer 210 can at least partially coat the pore walls 208 or at least partially fill the pores 202 of the porous material 200. If the pores 202 are not fully stuffed (filled) with the polymer 210, and a thicker layer of the polymer 210 is desired, the delivering step 104 and the reacting step 106 may be repeated one or more times as indicated by process arrow 108 in order to increase the amount of the polymer 210 in the pores 202. Some embodiments of the invention do not require complete filling of the pores 202 with the polymer 210. In fact, it is believed that a layer of the polymer 210 can be very effective in reducing plasma damage of the porous material 200. In addition, if complete filling is not needed, potential clogging of the pores 202 may be avoided.

The formation of a stable polymer 210 in the pores 202 requires a minimum molecular weight for the polymer 210 and/or a limited mobility within the pores 202 and neck areas over the expected range of subsequent utilization temperatures. The stability can further be improved by adding some amount of cross-linking between homo-polymers (i.e., di-vinyl monomers), and by increasing the non-covalent interactions between polymer chains by selecting monomers with side-chains.

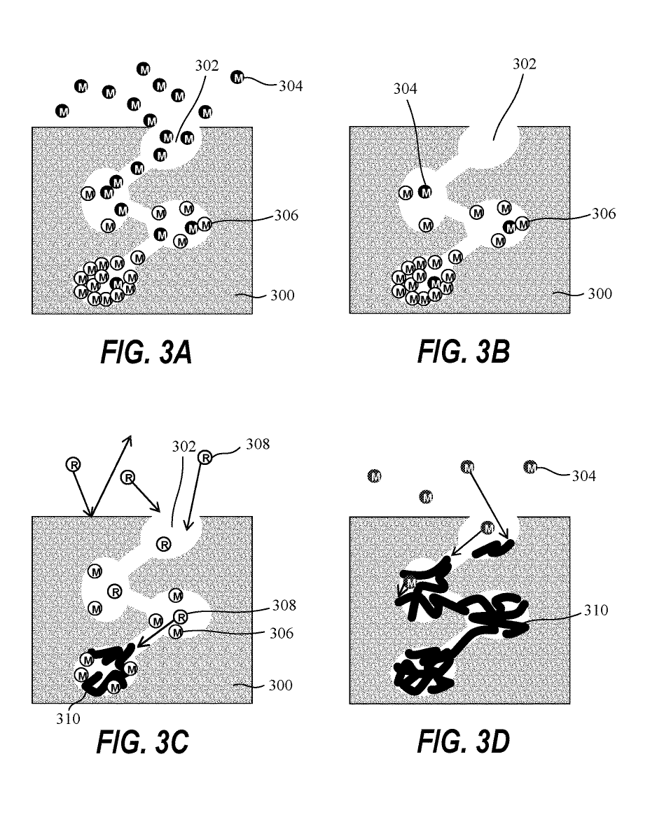

FIGS. 3A-3D show a chain-growth polymerization process according to one embodiment of the invention. Chain-growth polymerization is a polymerization process where unsaturated precursor molecules (e.g., monomers) add onto the active site of a growing polymer chain one at a time. Examples of unsaturated monomers include alkene and alicyclic compounds. Growth of the polymer occurs only at one (or possible more) ends and addition of each monomer unit regenerates the active site. This type of polymerization results in high molecular weight polymer being formed at low conversion. This final weight is determined by the rate of propagation compared to the rate of individual chain termination, which includes both chain transfer and chain termination steps.

FIG. 3A shows a porous material 300 containing interconnected pores 302. Precursor molecules 304 are delivered by gas phase exposure into the pores 302. Inside the pores 302, the precursor molecules 304 adsorb and form adsorbed precursor molecules 306. FIG. 3B shows the porous material following the formation of the adsorbed precursor molecules 306 and interruption of the gas phase exposure of the precursor molecules 304.

Thereafter, as depicted in FIG. 3C, polymerization is initiated in the pores 302 using, for example, free radicals 308. In one example, the free radicals 308 may be formed by flowing initiator molecules near a hot filament that cracks the initiator molecules. The temperature of the hot filament can, for example, be about 300° C., or less. Once initiated, the polymerization proceeds via chain-growth of polymer 310 during further gas exposure of precursor molecules 304 into the pores 302 (FIG. 3D). Examples of initiator molecules include peroxides which are compounds containing an oxygen-oxygen single bond. The simplest stable peroxide is hydrogen peroxide (H—O—O—H). Examples of other peroxides include R—O—O—R′, R—O—O—H, and R—CO—O—O—H, where R and R′ mark hydrocarbon moieties.

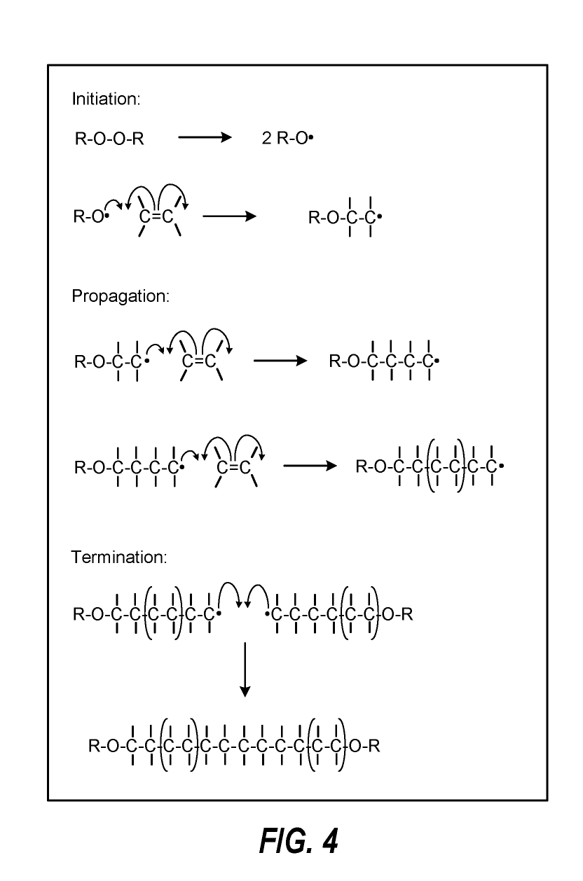

FIG. 4 schematically shows free radical polymerization according to an embodiment of the invention. The free radical polymerization process may be described by initiation, propagation, and termination. The initiation refers to formation of a free radical (e.g., R—O.) from pyrolysis of an initiator molecule (e.g., R—O—O—R) at low temperature. The free radical is a chemical trigger that reacts with the adsorbed precursor molecule (e.g., C₂H₄) on the pore walls to generate a polymer free radical (e.g., R—O—C—C.). Propagation refers to a further reaction of the polymer free radical with another precursor molecule, where a length of the polymer free radical is increased with each reaction. Termination refers to the reaction and quenching of two polymer free radicals.

FIGS. 4A-4C show a step-growth polymerization process according to one embodiment of the invention. Step-growth polymerization is a type of mechanism in which monomers can react to form first dimers, then trimers, longer oligomers and eventually long chain polymers. Due to the nature of the polymerization mechanism, a high extent of reaction is required to achieve high molecular weight.

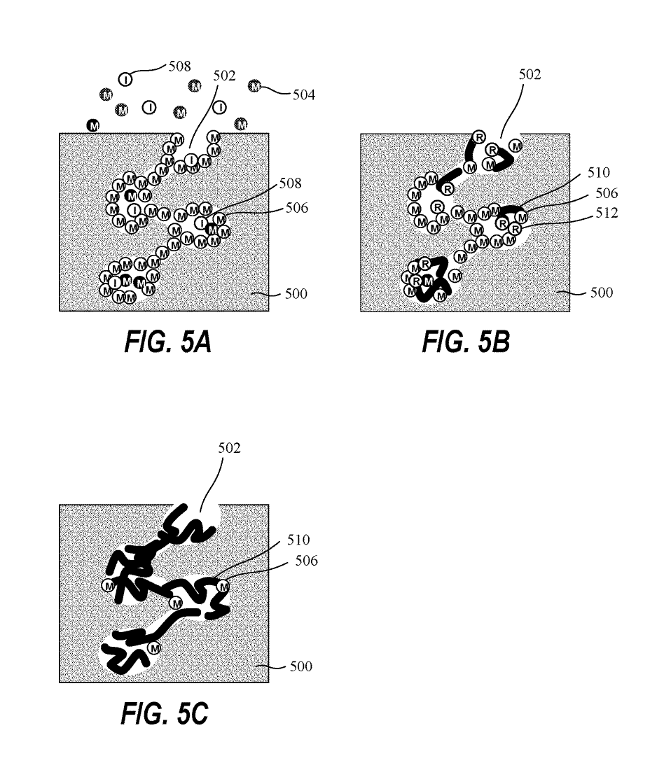

FIG. 5A shows a porous material 500 containing interconnected pores 502. Precursor molecules 504 and initiator molecules 508 are delivered by gas phase exposure into the pores 502 of the porous material 500. The precursor molecules 504 adsorb and form a saturation amount of adsorbed precursor molecules 506 in the pores 502. According to embodiments of the invention, the gas phase exposure of the precursor molecules 504 and the exposure of the porous material 500 to the initiator molecules 508 may be performed simultaneously, sequentially, or over-lapping one another.

As depicted in FIG. 5B, inside the pores 502, the initiator molecules 508 decompose to form free radicals 512 that initiate step-growth of a polymer 510. The formation of the free radicals 512 from the initiator molecules 508 can, for example, be triggered by temperature and/or electromagnetic radiation. Thereafter, as depicted in FIG. 5C, polymer propagation proceeds in the pores 502.

According to another embodiment, the polymerization process may be performed by heat-treating the porous material in the presence of an inert gas or a mixture of a reactive gas (e.g., O₂, H₂, or a combination thereof) and an inert gas. According to another embodiment, the polymerization process may be triggered by exposing the porous material to EM radiation, where the EM radiation can include emission at a wavelength within the ultraviolet (UV) spectrum, visible spectrum, infrared (IR) spectrum, or microwave spectrum, or combination thereof.

According to one embodiment, the polymerization process may be enhanced by exposing of the porous material to cross-linker molecules. This can be performed in parallel or in sequence to the gas phase exposure to the precursor molecules, initiator molecules and/or free radicals. The cross-linker molecules have more than one reactive site per molecule of which reactions with precursor molecules can increase the degree of crosslinking of the final polymer. The degree of crosslinking can be used to adjust the materials properties of the polymer, e.g., the molecular weight and the thermal decomposition onset temperature.

Following the formation of the polymer in the pores of the porous material, the porous material may be further processed. According to one embodiment, the stuffed porous material may be patterned to form a pattern therein using a patterning process. The patterning process can include a plasma etching process that utilizes a pattern mask formed of one or more layers using lithographic techniques. Thereafter, the remaining pattern mask is removed using an ashing process, which may include a plasma ashing process. The polymer within the pores of the porous material can protect the porous material from damage resulting from the plasma etching and/or ashing chemistry. In some examples, a pattern spacing of the pattern may be characterized by a dimension less than or equal to 50 nm. Alternatively, the pattern spacing of the pattern may be characterized by a dimension less than or equal to 30 nm.

Thereafter, the polymer may be removed from the pores in the porous material following the patterning of the porous material and prior to metallization of the pattern formed therein. Thereafter, the pattern may be metallized to form an electronic device. The metallization process may include conformally depositing a barrier layer in the pattern, overfilling the pattern with metal, performing a pre-planarization anneal process, and planarizing the metallized structure. For example, the metallization process may include a damascene process, or a dual damascene process.

According to another embodiment, the pattern may be metallized and, thereafter, the polymer may be removed from the pores in the porous material 200.

In various embodiments, the removal of the polymer from the pores may include: (a) irradiation by high energy photons, ions, or electrons to induce scission of the polymer, resulting in smaller molecules to ease diffusion out of the porous material; (b) addition of reactive species to either oxidize or hydrogenate the polymer, thus enhancing removability; (c) rapid selective heating of the porous material, or the polymer, or other surrounding materials, resulting in mechanical stretching or vibration to enhance the out-diffusion; or (d) any combination of two or more of (a)-(c).

The removal of the polymer can include heating a substrate holder upon which the porous material rests to a holder temperature greater than 100° C. and less than 450° C., or preferably less than 400° C., and while heating the substrate holder, optionally exposing the porous material to EM radiation, wherein the EM radiation includes emission at a wavelengths within the ultraviolet (UV) spectrum, visible spectrum, infrared (IR) spectrum, or microwave spectrum, or combination thereof.

The EM radiation may include UV radiation. The UV radiation may include, or consist essentially of UV wavelengths greater than or equal to 200 nm. Alternatively, the UV radiation may include, or consist essentially of UV wavelengths greater than or equal to 220 nm. Alternatively, the UV radiation may include, or consist essentially of UV wavelengths greater than or equal to 240 nm. Alternatively, the UV radiation may include, or consist essentially of UV wavelengths greater than or equal to 300 nm. Longer UV wavelengths can lower the risk of damage to the porous material, and reduce contamination of the metallized pattern.

The exposure to UV radiation may include substantially monochromatic radiation, or polychromatic radiation. The UV radiation may be applied continuously, or it may be pulsed. For example, the exposure to UV radiation may cycle between a high and low UV intensity, wherein an exposure time for exposure to said high UV intensity is less than 100 msec, or less than 10 msec, or less than 1 msec.

The exposure to UV radiation may further include exposure to IR radiation. The IR radiation may include substantially monochromatic radiation, or polychromatic radiation. The IR radiation may be applied continuously, or it may be pulsed. For example, the exposure to IR radiation may cycle between a high and low IR intensity, wherein an exposure time for exposure to said high IR intensity is less than 100 msec, or less than 10 msec, or less than 1 msec.

During exposure to EM radiation, the porous material may be translated, or rotated. Additionally, or alternatively, the EM radiation may be scanned across the substrate. Multiple beams of EM radiation may be produced and scanned across the substrate to improve throughput. Multiple passes of a beam of EM radiation may be performed to achieve the desired level of removal of the polymer. As an example, the porous material may be exposed to UV radiation, such as a UV flash exposure, followed by selective heating via a beam of EM radiation, such as UV or IR. Furthermore, the condition of the porous material may be monitored to assess the degree of removal of the polymer. As an example, the monitoring system may include a laser interferometer to measure changes in reflectivity.

A method for coating or filling a porous material using gas phase exposure has been disclosed in various embodiments. Although only certain embodiments of this invention have been described in detail above, those skilled in the art will readily appreciate that many modifications are possible in the embodiments without materially departing from the novel teachings and advantages of this invention. Accordingly, all such modifications are intended to be included within the scope of this invention.

What is claimed is:

1. A method of coating or filling a porous material, the method comprising:
providing the porous material;
delivering precursor molecules by gas phase exposure into pores of the porous material; and
reacting the precursor molecules to form a polymer inside the pores.

2. The method of claim 1, wherein the polymer does not fill the pores.

3. The method of claim 1, further comprising
repeating the delivering and reacting at least once to increase the amount of the polymer inside the pores.

4. The method of claim 1, wherein the porous material is mesoporous with pores having a diameter between 2 nm and 50 nm.

5. The method of claim 1, wherein the porous material is microporous with the pores having a diameter of less than 2 nm.

6. The method of claim 1, wherein the porous material has a metal organic framework (MOF).

7. The method of claim 1, wherein the porous material has a covalent organic framework (COF).

8. The method of claim 1, wherein the porous material is a metal foam.

9. The method of claim 1, wherein the porous material contains a membrane.

10. The method of claim 1, wherein the precursor molecules include monomers, dimers or oligomers of low molecular weight organic compounds that are capable of polymerization.

11. The method of claim 1, wherein the precursor molecules include a vinyl functional group (—C═C—).

12. The method of claim 1, wherein the precursor molecules include carbon-carbon triple bonds (—C≡C—).

13. The method of claim 1, wherein the precursor molecules include two or more different reactive molecules that are able to react and form molecules with much higher molecular weight.

14. The method of claim 13, wherein one precursor molecule contains a hydroxyl group (—OH) and another precursor molecule contains an amine group (—NH₂).

15. The method of claim 13, wherein one precursor molecule contains a hydroxyl group (—OH) and another precursor molecule contains a carboxylic acid group (—COOH) or an acyl chloride (—COCl).

16. The method of claim 1, wherein the reacting is performed by heat-treating the porous material in a gaseous environment.

17. The method of claim 1, wherein the reacting is performed by exposing the porous material to electromagnetic (EM) radiation.

18. The method of claim 1, wherein the reacting includes free radicals formed from initiator molecules.

19. The method of claim 15, wherein the free radicals are generated by thermal decomposition of the initiator molecules.

20. The method of claim 15, wherein the initiator molecules include a peroxide.

21. The method of claim 17, wherein the peroxide is selected from the group consisting of hydrogen peroxide (H—O—O—H), R—O—O—H, R—O—O—R′, and R—CO—O—O—H, where R and R′ mark hydrocarbon moieties.

22. The method of claim 1, wherein the reacting includes exposing the porous material to cations and free radicals that are generated in a plasma.

23. The method of claim 1, further comprising
generating a vertical temperature gradient across a thickness of the porous material from a top surface of the porous material to a bottom surface of the porous material.

24. The method of claim 1, further comprising
delivering cross-linker molecules into the pores of the porous material, wherein the cross-linker molecules contain at least two reactive sites.

25. The method of claim 1, further comprising
controlling the partial pressure of the precursor and initiator, and the temperature of the substrate and the gas phase in order to achieve desired molecular weight of the polymer.

26. The method of claim 1, further comprising
controlling the ratio of the partial pressure of the precursor, initiator and cross-linker, and the temperature of the substrate and the gas phase in order to achieve desired materials properties, such as molecular weight and thermal decomposition onset temperature.

27. The method of claim 1, further comprising
treating the porous material prior to delivering the precursor molecules, wherein the treating includes one or more steps selected from the group consisting of coating the pores with a chemical, exposing the porous material to a reactive gas containing an oxidation species or a reducing species, exposing the porous material to UV light, exposing the porous material to an electron beam or an ion beam, and exposing the porous material to a gas phase plasma.
